(19) United States
(12) Patent Application Publication
(10) Pub. No.: US 2020/0066645 A1
(43) Pub. Date: Feb. 27, 2020

(54) MICROELECTRONIC DEVICES AND METHODS FOR ENHANCING INTERCONNECT RELIABILITY PERFORMANCE USING TUNGSTEN CONTAINING ADHESION LAYERS TO ENABLE COBALT INTERCONNECTS

(71) Applicant: INTEL CORPORATION, Santa Clara, CA (US)

(72) Inventors: Jason A. FARMER, Hillsboro, OR (US); Jeffrey S. LEIB, Hillsboro, OR (US); Michael L. MCSWINEY, Scappoose, OR (US); Harsono S. SIMKA, Saratoga, CA (US); Daniel B. BERGSTROM, Lake Oswego, OR (US)

(73) Assignee: Intel Corporation, Santa Clara, CA (US)

(21) Appl. No.: 16/324,087

(22) PCT Filed: Sep. 30, 2016
(86) PCT No.: PCT/US2016/055032

§ 371 Date: Feb. 7, 2019

(51) Int. Cl. H01L 23/532; H01L 21/285; H01L 21/768; H01L 23/522

(52) U.S. Cl. CPC H01L 23/53209; H01L 21/28562; H01L 23/5226; H01L 21/76862; H01L 21/76843

(57) ABSTRACT

Embodiments of the invention include a microelectronic device that includes a substrate having a layer of dielectric material that includes a feature with a depression, a Tungsten containing barrier liner layer formed in the depression of the feature, and a Cobalt conductive layer deposited on the Tungsten containing barrier liner layer in the depression of the feature. The Tungsten containing barrier liner layer provides adhesion for the Cobalt conductive layer.

### FIELD OF THE INVENTION

Embodiments of the present invention relate generally to the manufacture of semiconductor devices. In particular, embodiments of the present invention relate to microelectronic devices and methods for enhancing interconnect reliability performance using Tungsten (W) containing adhesion layers to enable Cobalt (Co) interconnects.

### BACKGROUND OF THE INVENTION

The current state of the art for semiconductor material interconnects is copper (Cu). As device dimensions shrink, the resistivity increases and electromigration performance issues cause Cu metal lines to be less desirable.

### BRIEF DESCRIPTION OF THE DRAWINGS

FIG. 1 illustrates a process for enhancing interconnect reliability performance using using Tungsten (W) containing adhesion layers to enable Cobalt (Co) interconnects for transistor devices of microelectronic devices (e.g., integrated circuit chips) in accordance with one embodiment.

FIG. 2 illustrates an electrical interconnect structure of a microelectronic device with the interconnect structure including a W containing barrier liner layer in accordance with one embodiment.

FIG. 3 illustrates a cross-sectional view of an interconnect structure 500 having a conventional TiN liner.

FIG. 4 illustrates a cross-sectional view of an interconnect structure 600 having a W containing liner in accordance with one embodiment.

FIG. 5 illustrates a computing device 900 in accordance with one embodiment.

### DETAILED DESCRIPTION OF THE INVENTION

Described herein are microelectronic devices that are designed to enhance interconnect reliability performance using Tungsten (W) containing adhesion layers to enable Cobalt (Co) interconnects. In the following description, various aspects of the illustrative implementations will be described using terms commonly employed by those skilled in the art to convey the substance of their work to others skilled in the art. However, it will be apparent to those skilled in the art that embodiments of the present invention may be practiced with only some of the described aspects. For purposes of explanation, specific numbers, materials and configurations are set forth in order to provide a thorough understanding of the illustrative implementations. However, it will be apparent to one skilled in the art that embodiments of the present invention may be practiced without the specific details. In other instances, well-known features are omitted or simplified in order to not obscure the illustrative implementations.

Various operations will be described as multiple discrete operations, in turn, in a manner that is most helpful in understanding embodiments of the present invention, however, the order of description should not be construed to imply that these operations are necessarily order dependent. In particular, these operations need not be performed in the order of presentation.

Electronic connections between the electronic devices (e.g., transistors) in an integrated circuit (IC) chip are currently typically created using copper metal or alloys of copper metal. Devices in an IC chip can be placed not only across the surface of the IC chip but devices can also be stacked in a plurality of layers on the IC chip. Electrical interconnections between electronic devices that make up the IC chip are built using vias and trenches that are filled with conducting material. Layer(s) of insulating materials, frequently, low-k dielectric materials, separate the various components and devices in the IC chip. The substrate on which the devices of the IC circuit chip are built is, for example, a silicon wafer or a silicon-on-insulator substrate. Silicon wafers are substrates that are typically used in the semiconductor processing industry, although embodiments of the invention are not dependent on the type of substrate used. The substrate could also be comprised of germanium, indium antimonide, lead telluride, indium arsenide, indium phosphide, gallium arsenide, gallium antimonide, and or other Group III-V materials either alone or in combination with silicon or silicon dioxide or other insulating materials. IC devices that make up the chip are built on the substrate surface.

At least one dielectric layer is deposited on the substrate. Dielectric materials include, but are not limited to, silicon dioxide (SiO2), low-k dielectrics, silicon nitrides, and or silicon oxynitrides. The dielectric layer optionally includes pores or other voids to further reduce its dielectric constant. Typically, low-k films are considered to be any film with a dielectric constant smaller than that of SiO₂ which has a dielectric constant of about 4.0. Low-k films having dielectric constants of about 1 to about 4.0 are typical of current semiconductor fabrication processes. The production of integrated circuit device structures often also includes placing a silicon dioxide film or layer, or capping layer on the surface of low-k (low dielectric constant) ILD (inter-layer dielectric) films. Low-k films can be, for example, boron, phosphorous, or carbon doped silicon oxides. Carbon-doped silicon oxides can also be referred to as carbon-doped oxides (CDOs) and organo-silicate glasses (OSGs).

To form electrical interconnects, dielectric layers are patterned to create one or more trenches and or vias within which metal interconnects will be formed. The terms trenches and vias are used herein because these are the terms commonly associated with the features that are used to form metal interconnects. In general, a feature used to form a metal interconnect is a depression having any shape formed in a substrate or layer deposited on the substrate. The feature is filled with conducting interconnect material. The trenches and or vias may be patterned (created) using conventional wet or dry etch semiconductor processing techniques. Dielectric materials are used to isolate electrically metal interconnects from the surrounding components. Barrier liner layers are used between the metal interconnects and the dielectric materials to prevent metal (such as copper) migration into the surrounding materials. Device failure can occur, for example, in situations in which copper metal is in contact with dielectric materials because the copper metal can ionize and penetrate into the dielectric material. Barrier layers placed between a dielectric material, silicon, and or other materials and the copper interconnect can also serve to promote adhesion of the copper to the other material(s).

Due to issues with Cu interconnect at shrinking device dimensions (e g, minimum line width of 20-70 nanometers), the present design integrates Cobalt (Co) interconnects into microelectronic devices to provide lower resistivity in comparison to Copper and improved electromigration performance at relevant device dimensions in comparison to Copper. In order to integrate Cobalt into semiconductor devices an adhesion layer (liner) is needed to prevent void formation at the liner-to-Co interface. Voids in semiconductor devices result in high resistance failures (open circuits), and electromigration failures (short device lifetime). Liners can reduce voiding both by enhancing adhesion of Co to the device and by limiting metal diffusion between lines.

This present design uses liners containing tungsten (W) or tungsten nitride (WN) to enable adhesion between the liner and Co in semiconductor devices for both enhanced adhesion and protection against metal diffusion between lines. Deposition of the liner can be done using atomic layer deposition (ALD), chemical vapor deposition (CVD) or physical vapor deposition (PVD). Using W/WN enables a thin liner (e.g., 1-25 angstroms) to be used meeting via/line resistance goals. Use of ALD/CVD enables the present design to provide high aspect ratio structures.

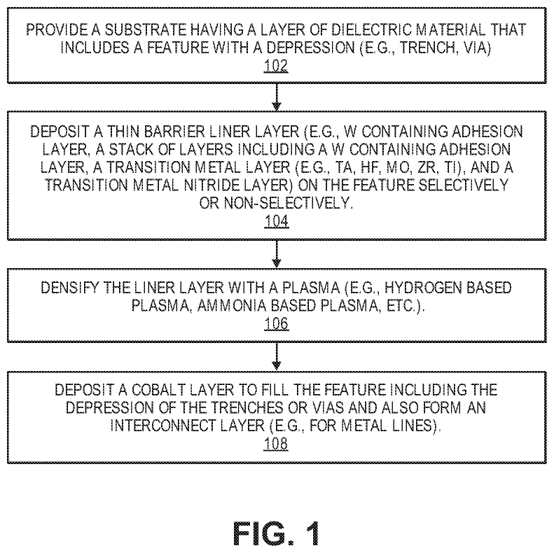

FIG. 1 illustrates a process for enhancing interconnect reliability performance using Tungsten (W) containing adhesion layers to enable Cobalt (Co) interconnects for transistor devices of microelectronic devices (e.g., integrated circuit chips) in accordance with one embodiment. In FIG. 1, a substrate having a layer of dielectric material that includes a feature with a depression (e.g., trench, via) that is to be filled with a conducting metal to form an electrically conducting interconnect is provided at operation 102. The trench or via is a depression that is typically formed in a dielectric layer, such as an ILD layer through an etching process used in the semiconductor industry. The walls and bottom of the trench or via (the side(s) of the depression) can be deposited with a thin barrier liner layer (e.g., W containing adhesion layer, a stack of layers including a W containing adhesion layer, a transition metal layer (e.g., Ta, Hf, Mo, Zr, Ti), and a transition metal nitride layer) at operation 104. The liner layer can be deposited selectively in desired regions such as the trenches or vias or the liner layer can be deposited as a blanket layer on the microelectronic device. The thin metallic liner layer is deposited by ALD, CVD, or PVD, for example. At operation 106, the liner layer is densified with a plasma (e.g., hydrogen based plasma, ammonia based plasma, etc.). The operations 104 and 106 can be cyclically repeated until achieving a desired thickness and densification of the barrier liner layer. A Cobalt layer is deposited at operation 108 to fill the feature including the depression of the trenches or vias and also form an interconnect layer (e.g., for metal lines). The Cobalt layer is deposited by ALD, PVD, or CVD, for example. In embodiments of the invention, the barrier liner layer has an average thickness of 1 to 25 angstroms.

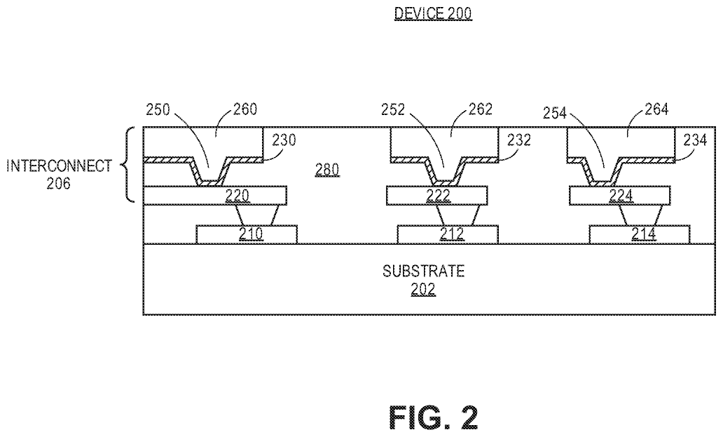

FIG. 2 illustrates an electrical interconnect structure of a microelectronic device with the interconnect structure including a W containing barrier liner layer in accordance with one embodiment. The device 200 includes a substrate 202, devices 210, 212, 214 (e.g., transistors, CMOS devices, memory devices, etc.), an interconnect structure 206, and dielectric layer(s) 280 for electrical isolation between metal lines 220, 222, 224, 260, 262, 264 and vias 250, 252, and 254 of the interconnect structure. A tungsten containing barrier liner layer 230, 232, and 234 provides an adhesion layer to prevent void formation upon depositing Cobalt to form the vias 250, 252, 254 and lines 260, 262, and 264. A tungsten containing barrier liner layer enables a thin liner to be used for achieving via and line resistance goals. ALD and CVD can be used for depositing the tungsten containing barrier liner layer for high aspect ratio structures (e.g., aspect ratios of x to y). The ALD and CVD processes can include cyclic alternating operations of depositing the tungsten containing barrier liner layer and densifying this liner layer. The densification can be a plasma Hydrogen based operation or a plasma Ammonia based operation. In one example, dopants can be used in the tungsten containing barrier liner layer (e.g., W, WN, stack with W, transition metal, nitride of transition metal, etc.) to modify adhesion and diffusion barrier properties. In one example, dopants modify the adhesion and Cobalt diffusion barrier properties of the tungsten containing barrier liner layer (e.g., W, WN) by creating WX or W×N liners (e.g., with X being Boron, Phosphorus, Carbon, Silicon, or Aluminum).

Precursors of CVD and ALD processes can be used to deposit the tungsten containing barrier liner layer selectively (e.g., selective to conductive films versus non-conductive films) in certain targeted regions of the interconnect structure (e.g., depressions, vias, trenches, lines) or as a blanket film. PVD liners may also be used at certain device dimensions (e.g., line widths of 20-70 nanometers).

In one example of pre-cursor selection for the W containing liner, the CVD/ALD W film generated can be W, WN, WC, WCN or any other film required and useful to the overall integrated process. W precursors used can take one of many forms. W precursors with unsubstituted and substituted cyclopentadienyl ligands can be used and fall in the general formulas W(Cp)R₃, W(Cp)₂R₂, and W(Cp)₃R where “Cp” can be cyclopentadienyl, methylcyclopentadenyl, ethylcyclopentadienyl, tert-butylcyclopentadenyl, isopropylcyclopentadienyl, or any other substituted cyclopentadiene ligand. In the embodiment above “R” can be carbonyl, hydride, nitrosyl, trimethylsilyl, methyltrimethylsilyl, or amido.

W precursors can also take the form of a mixed amino/imino compound-generally of the formula W(NR¹₂)₂(NR²)₂. In this embodiment, R¹ and R² can be a methyl, ethyl, propyl, isopropyl, tert-butyl, trimethylsilyl, methyltrimethylsilyl, or other suitable group, but do not need to be the same moity. Another embodiment with the general formula W(NR¹R²)₂(NR³)₂ where once again the moieties above could be applied, but where none are required to be the same.

Use of Cobalt to fill semiconductor device interconnects (lines and vias) can be performed in high volume manufacturing in accordance with the present design due to the use of W containing adhesion layers (liners) to enable Cobalt interconnects. In one example, Cobalt fill of interconnects is discussed herein using the damascene technique in which the metal fills features that had previously been patterned into a wafer and the metal is then polished flat. Damascene features primarily include two structures: lines (interconnects for the current metal layer) and vias (interconnects to layers below the current layer). The two main challenges for metal fill of lines and vias is the aspect ratio of the structures and the materials that define the structures (i.e., the sides and bottom of the structures). Via structures are challenging for Cobalt void formation, due to via interconnect to layers below the current layer. In this way Cobalt vias can land on incompatible materials (e.g., materials containing halogens [F, Cl, etc.]). Via structures are also challenging for Cobalt void formation due to the geometry of via structures, which increases capillary forces and this exposes poor liner-to-Cobalt adhesion.

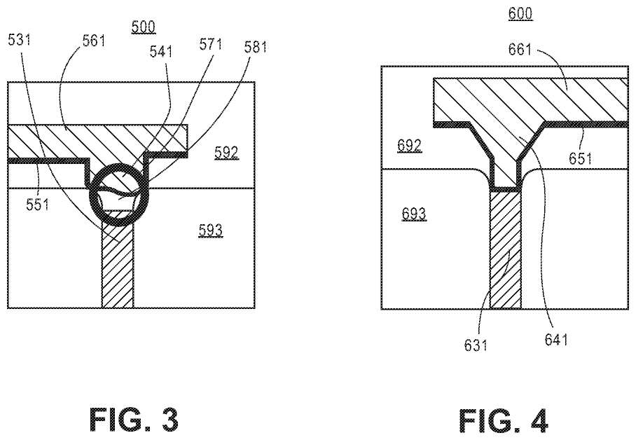

FIG. 3 illustrates a cross-sectional view of an interconnect structure 500 having a conventional TiN liner. The structure 500 includes metal layers 531, via 541, Cobalt metal layer 561, and dielectric layer(s) 592-593 for electrical isolation between metal layers and vias. The TiN barrier liner layer 551 provides an adhesion layer that is not able to prevent void formation upon depositing Cobalt metal layer 561 to form the vias and lines. The region 571 includes void 581 in the via due to insufficient Cobalt metal to TiN liner layer adhesion. The void will act as electrical opens for the intended electrical connection between the metal layers 531 and the Cobalt metal layers 561. In one example, the metal layer 531 is a different metal (e.g., Copper) than the Cobalt metal layer 561.

FIG. 4 illustrates a cross-sectional view of an interconnect structure 600 having a W containing liner in accordance with one embodiment. The structure 600 includes metal layer 631, via 641, Cobalt metal layer 661, and dielectric layer(s) 692-693 for electrical isolation between metal layers and vias. A Tungsten containing barrier liner layer 651 (e.g., WN liner layer) provides an adhesion layer to prevent void formation upon depositing Cobalt metal layer 661 to form the vias and lines. The via include no voids due to sufficient Cobalt metal to W containing liner layer adhesion. In one example, the metal layer 631 is a different metal (e.g., Copper) than the Cobalt metal layer 661.

It will be appreciated that, in a system on a chip embodiment, the die may include a processor, memory, communications circuitry and the like. Though a single die is illustrated, there may be none, one or several dies included in the same region of the wafer.

In one embodiment, the microelectronic device may be a crystalline substrate formed using a bulk silicon or a silicon-on-insulator substructure. In other implementations, the microelectronics device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of embodiments of the present invention.

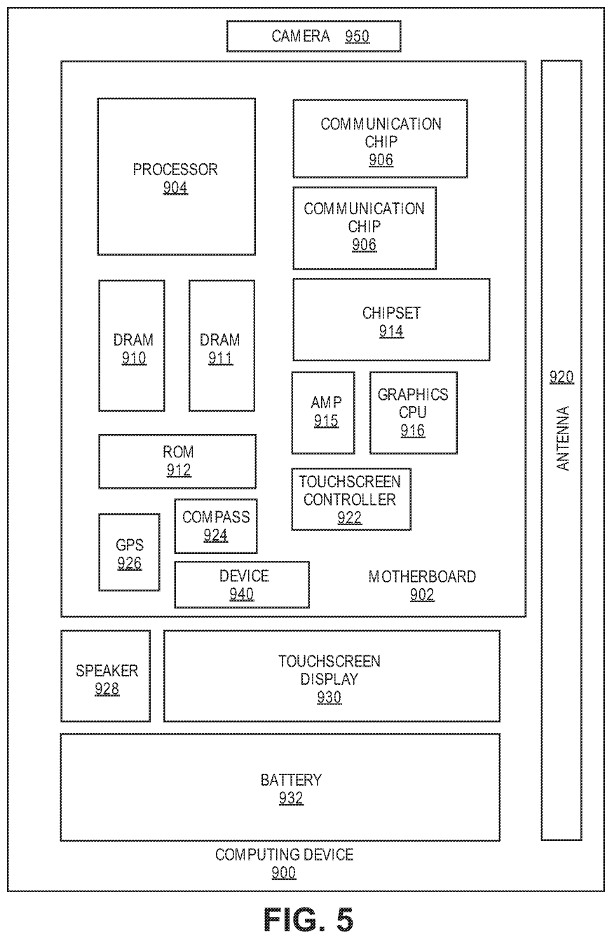

FIG. 5 illustrates a computing device 900 in accordance with one embodiment of the invention. The computing device 900 houses a board 902. The board 902 may include a number of components, including but not limited to at least one processor 904 and at least one communication chip 906. The at least one processor 904 is physically and electrically coupled to the board 902. In some implementations, the at least one communication chip 906 is also physically and electrically coupled to the board 902. In further implementations, the communication chip 906 is part of the processor 904. In one example, any of the components of the computing device include at least one microelectronic device (e.g., microelectronic device 200) having interconnect structures (e.g., interconnect structures 400, 500, 600) with W containing barrier liner layers. The computing device 900 may also include a separate microelectronic device 940 (e.g., microelectronic device 200).

Depending on its applications, computing device 900 may include other components that may or may not be physically and electrically coupled to the board 902. These other components include, but are not limited to, volatile memory (e.g., DRAM 910, 911), non-volatile memory (e.g., ROM 912), flash memory, a graphics processor 916, a digital signal processor, a crypto processor, a chipset 914, an antenna unit 920, a display, a touchscreen display 930, a touchscreen controller 922, a battery 932, an audio codec, a video codec, a power amplifier 915, a global positioning system (GPS) device 926, a compass 924, a gyroscope, a speaker, a camera 950, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), WiGig, IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi, WiGig, and Bluetooth and a second communication chip 906 may be dedicated to longer range wireless communications such as GPS, EDGE, GPRS, CDMA, WiMAX, LTE, Ev-DO, 5G, and others.

The at least one processor 904 of the computing device 900 includes an integrated circuit die packaged within the at least one processor 904. In some implementations of embodiments of the invention, the integrated circuit die of the processor includes one or more devices, such as microelectronic devices (e.g., microelectronic device 200, etc.) in accordance with implementations of embodiments of the invention. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the invention, the integrated circuit die of the communication chip includes one or more microelectronic devices (e.g., microelectronic device 200, etc.).

The following examples pertain to further embodiments. Example 1 is a microelectronic device that includes a substrate having a layer of dielectric material that includes a feature with a depression, a Tungsten containing barrier liner layer formed in the depression of the feature, and a Cobalt conductive layer deposited on the Tungsten containing barrier liner layer in the depression of the feature with the Tungsten containing barrier liner layer to provide adhesion for the Cobalt conductive layer.

In example 2, the subject matter of example 1 can optionally include the Tungsten containing barrier liner layer comprising a Tungsten Nitride layer.

In example 3, the subject matter of any of examples 1-2 can optionally include the Tungsten containing barrier liner layer comprises a Tungsten containing layer and at least one of a transition metal layer and a transition metal nitride layer.

In example 4, the subject matter of any of examples 1-3 can optionally include the Cobalt conductive layer being deposited on the Tungsten containing barrier liner layer in the depression of the feature without voids being formed.

In example 5, the subject matter of any of examples 1-4 can optionally include the Tungsten containing barrier liner layer having a thickness of 1 to 25 Angstroms.

In example 6, the subject matter of any of examples 1-5 can optionally include the Tungsten containing barrier liner layer includes at least one dopant to modify adhesion and diffusion barrier properties.

In example 7, the subject matter of any of examples 1-6 can optionally include the Tungsten containing barrier liner layer being deposited with chemical vapor deposition or atomic layer deposition with organometallic precursors and no halogen based precursors.

Example 8 is a microelectronic device comprising a substrate having a layer of dielectric material that includes a feature with a depression, a Tungsten containing barrier liner layer deposition in the depression of the feature, and a Cobalt conductive layer deposited on the Tungsten containing barrier liner layer in the depression of the feature with Tungsten precursors for the deposition of the Tungsten containing barrier liner layer being compatible with the Cobalt conductive layer.

In example 9, the subject matter of example 8 can optional include the Tungsten containing barrier liner layer that comprises at least one of a Tungsten Nitride layer, a Tungsten Carbide layer, and a Tungsten Carbide Nitride layer.

In example 10, the subject matter of any of examples 8-9 can optionally include the Tungsten (W) precursors for the deposition of the Tungsten containing barrier liner layer comprising unsubstituted and substituted cyclopentadienyl ligands.

In example 11, the subject matter of any of examples 8-10 can optionally include the cyclopentadienyl ligands comprising chemical formulas of W(Cp)R₃, W(Cp)₂R₂, and W(Cp)₃R where Cp is cyclopentadienyl, methylcyclopentadenyl, ethylcyclopentadienyl, tert-butylcyclopentadenyl, isopropylcyclopentadienyl, or any other substituted cyclopentadiene ligand and R is carbonyl, hydride, nitrosyl, trimethylsilyl, methyltrimethylsilyl, or amido.

In example 12, the subject matter of any of examples 8-12 can optionally include the Tungsten (W) precursors for the deposition of the Tungsten containing barrier liner layer comprising a mixed amino or imino compound having a chemical formula of W(NR¹₂) 2(NR²) 2 with R¹ and R² being a methyl, ethyl, propyl, isopropyl, tert-butyl, trimethylsilyl, methyltrimethylsilyl, or other suitable group.

In example 13, the subject matter of any of examples 8-12 can optionally include R¹ and R² not being the same moity.

In example 14, the subject matter of any of examples 8-13 can optionally include the Tungsten (W) precursors for the deposition of the Tungsten containing barrier liner layer comprising a chemical formula of W(NR¹R²)₂(NR³)₂ with R¹ and R² being a methyl, ethyl, propyl, isopropyl, tert-butyl, trimethylsilyl, methyltrimethylsilyl, or other suitable group.

In example 15, the subject matter of any of examples 8-14 can optionally include the Tungsten containing barrier liner layer having a thickness of 1 to 25 Angstroms.

In example 16, the subject matter of any of examples 8-15 can optionally include the Tungsten containing barrier liner layer being deposited with chemical vapor deposition or atomic layer deposition with organometallic precursors and no halogen based precursors.

Example 17 is a method comprising providing a substrate having a layer of dielectric material that includes a feature with a depression that is to be filled with a conducting metal to form an electrically conducting interconnect, depositing a Tungsten containing barrier liner layer on the feature, and depositing a Cobalt layer to fill the feature including the depression and also form an interconnect layer.

In example 18, the subject matter of example 17 can optionally include densifying the Tungsten containing barrier liner layer with a hydrogen based plasma or an ammonia based plasma.

In example 19, the subject matter of any of examples 17-18 can optionally include the Tungsten containing barrier liner layer comprising a Tungsten Nitride layer.

In example 20, the subject matter of any of examples 17-19 can optionally include the Tungsten containing barrier liner layer comprising a Tungsten containing layer and at least one of a transition metal layer and a transition metal nitride layer.

1. A microelectronic device comprising:
a substrate having a layer of dielectric material that includes a feature with a depression;
a Tungsten containing barrier liner layer formed in the depression of the feature; and
a Cobalt conductive layer deposited on the Tungsten containing barrier liner layer in the depression of the feature with the Tungsten containing barrier liner layer to provide adhesion for the Cobalt conductive layer.

2. The microelectronic device of claim 1, wherein the Tungsten containing barrier liner layer comprises a Tungsten Nitride layer.

3. The microelectronic device of claim 1, wherein the Tungsten containing barrier liner layer comprises a Tungsten containing layer and at least one of a transition metal layer and a transition metal nitride layer.

4. The microelectronic device of claim 1 wherein Cobalt conductive layer is deposited on the Tungsten containing barrier liner layer in the depression of the feature without voids being formed.

5. The microelectronic device of claim 1, wherein the Tungsten containing barrier liner layer has a thickness of 1 to 25 Angstroms.

6. The microelectronic device of claim 1, wherein the Tungsten containing barrier liner layer includes at least one dopant to modify adhesion and diffusion barrier properties.

7. The microelectronic device of claim 1, wherein the Tungsten containing barrier liner layer is deposited with chemical vapor deposition or atomic layer deposition with organometallic precursors and no halogen based precursors.

8. A microelectronic device comprising:
a substrate having a layer of dielectric material that includes a feature with a depression;
a Tungsten containing barrier liner layer deposition in the depression of the feature; and
a Cobalt conductive layer deposited on the Tungsten containing barrier liner layer in the depression of the feature with Tungsten precursors for the deposition of the Tungsten containing barrier liner layer being compatible with the Cobalt conductive layer.

9. The microelectronic device of claim 8, wherein the Tungsten containing barrier liner layer comprises at least one of a Tungsten Nitride layer, a Tungsten Carbide layer, and a Tungsten Carbide Nitride layer.

10. The microelectronic device of claim 8, wherein the Tungsten (W) precursors for the deposition of the Tungsten containing barrier liner layer comprise unsubstituted and substituted cyclopentadienyl ligands.

11. The microelectronic device of claim 10 wherein the cyclopentadienyl ligands comprise chemical formulas of W(Cp)R₃, W(Cp)₂R₂, and W(Cp)₃R where Cp is cyclopentadienyl, methylcyclopentadenyl, ethylcyclopentadienyl, tert-butylcyclopentadenyl, isopropylcyclopentadienyl, or any other substituted cyclopentadiene ligand and R is carbonyl, hydride, nitrosyl, trimethylsilyl, methyltrimethylsilyl, or amido.

12. The microelectronic device of claim 8, wherein the Tungsten (W) precursors for the deposition of the Tungsten containing barrier liner layer comprise a mixed amino or imino compound having a chemical formula of W(NR¹₂)₂(NR²)₂ with R¹ and R² being a methyl, ethyl, propyl, isopropyl, tert-butyl, trimethylsilyl, methyltrimethylsilyl, or other suitable group.

13. The microelectronic device of claim 12, wherein R¹ and R² are not the same moity.

14. The microelectronic device of claim 8, wherein the Tungsten (W) precursors for the deposition of the Tungsten containing barrier liner layer comprise a chemical formula of W(NR¹R²)₂(NR³)₂ with R¹ and R² being a methyl, ethyl, propyl, isopropyl, tert-butyl, trimethylsilyl, methyltrimethylsilyl, or other suitable group.

15. The microelectronic device of claim 8, wherein the Tungsten containing barrier liner layer has a thickness of 1 to 25 Angstroms.

16. The microelectronic device of claim 8, wherein the Tungsten containing barrier liner layer is deposited with chemical vapor deposition or atomic layer deposition with organometallic precursors and no halogen based precursors.

17. A method comprising:
providing a substrate having a layer of dielectric material that includes a feature with a depression that is to be filled with a conducting metal to form an electrically conducting interconnect;
depositing a Tungsten containing barrier liner layer on the feature; and
depositing a Cobalt layer to fill the feature including the depression and also form an interconnect layer.

18. The method of claim 17, further comprising:
densifying the Tungsten containing barrier liner layer with a hydrogen based plasma or an ammonia based plasma.

19. The method of claim 17, wherein the Tungsten containing barrier liner layer comprises a Tungsten Nitride layer.

20. The method of claim 17, wherein the Tungsten containing barrier liner layer comprises a Tungsten containing layer and at least one of a transition metal layer and a transition metal nitride layer.
